(19) United States
(12) Patent Application Publication
(10) Pub. No.: US 2023/0262992 A1
(43) Pub. Date: Aug. 17, 2023

(54) MRAM INTERCONNECT INTEGRATION WITH SUBTRACTIVE METAL PATTERNING

(71) Applicant: International Business Machines Corporation, Armonk, NY (US)

(72) Inventors: Ruilong Xie, Niskayuna, NY (US); Kangguo Cheng, Schenectady, NY (US); Julien Frougier, Albany, NY (US)

(21) Appl. No.: 17/651,169

(22) Filed: Feb. 15, 2022

(51) Int. Cl. H01L 27/22; H01L 23/522; H01L 23/528; H01L 43/02; H01L 43/12

(52) U.S. Cl. CPC H01L 27/222; H01L 23/5226; H01L 23/5283; H01L 43/02; H01L 43/12

(57) ABSTRACT

A semiconductor component includes a first metal layer, a second metal layer, and an MRAM cell. The MRAM cell has a height that is equal to a distance between the first metal layer and the second metal layer. The semiconductor component further includes a first via layer, a third metal layer, and a second via layer. The first via layer, the third metal layer, and the second via layer have a combined height that is equal to the MRAM cell height.

### BACKGROUND

The present disclosure relates to the electrical, electronic, and computer fields. In particular, the present disclosure relates to computer memory devices and methods of making computer memory devices.

Random-access memory (RAM) is a form of computer memory that can be read and changed. RAM is typically used to store working data and machine code. Non-volatile random-access memory (NVRAM) is RAM that retains data without applied power. Magnetoresistive random-access memory (MRAM) is a type of NVRAM which stores data in magnetic domains.

### SUMMARY

Embodiments of the present disclosure include a semiconductor component. The semiconductor component includes a first metal layer, a second metal layer, and an MRAM cell. The MRAM cell has a height that is equal to a distance between the first metal layer and the second metal layer. The semiconductor component further includes a first via layer, a third metal layer, and a second via layer. The first via layer, the third metal layer, and the second via layer have a combined height that is equal to the MRAM cell height.

In such embodiments of the present disclosure, because the combined height of the first via layer, the third metal layer, and the second via layer are equal to the height of the MRAM cell, such embodiments advantageously enable in-line integration of an MRAM cell with corresponding interconnect structures without incurring the drawbacks introduced by increasing the height of a single via.

In accordance with at least some embodiments of the present disclosure, the MRAM cell can be arranged between the first metal layer and the second metal layer and the first via layer, the third metal layer, and the second via layer can be arranged between the first metal layer and the second metal layer.

In such embodiments of the present disclosure, the MRAM cell is formed in-line with an interconnect structure that includes two vias and an intervening metal line. Because the MRAM cell and the corresponding interconnect structure are arranged between the same metal layers, the MRAM cell is advantageously able to be formed in-line with a lower level via without having to increase the height of that via to accommodate the height of the MRAM cell.

Additional embodiments of the present disclosure include a method of forming a semiconductor component. The method includes forming a first metal layer. The method further includes forming an MRAM stack in direct contact with the first metal layer. The method further includes forming a layer of conductive material. The method further includes selectively removing a first portion of the layer of conductive material to form a second metal layer and selectively removing a second portion of the layer of conductive material to form a via layer. The method further includes forming a third metal layer in direct contact with the MRAM stack and in direct contact with the via layer.

Such embodiments of the present disclosure advantageously enable subtractive formation of interconnect structures such that the interconnect structures are in direct contact with the same metal layer as an MRAM cell. Accordingly, such embodiments facilitate the formation of multiple interconnect structures that correspond to an MRAM cell thereby avoiding the drawbacks introduced by increasing the height of a single via. Additionally, such embodiments enable detection of the method due to structural effects resulting from subtractive formation.

Additional embodiments of the present disclosure include a semiconductor component. The semiconductor component includes a first metal layer and a second metal layer spaced apart from the first metal layer. The semiconductor component further includes an MRAM stack arranged in a memory region of the semiconductor component. The MRAM stack is in direct contact with a substantially planar uppermost surface of the first metal layer and is in direct contact with a substantially planar lowermost surface of the second metal layer. The semiconductor component further includes a counterpart arrangement arranged in a logic region of the semiconductor component. The counterpart arrangement is in direct contact with the uppermost surface of the first metal layer and is in direct contact with the lowermost surface of the second metal layer. The counterpart arrangement includes a first via layer, a third metal layer, and a second via layer.

Such embodiments of the present disclosure advantageously enable the formation of an MRAM cell in-line with a combination of interconnect structures, including a via. Accordingly, such embodiments advantageously enable in-line integration of an MRAM cell with a corresponding via without incurring the drawbacks introduced by increasing the height of the via. Accordingly, such embodiments enable in-line integration of an MRAM cell with lower level vias.

Additional embodiments of the present disclosure include a method of forming a semiconductor component. The method includes forming a first metal layer having an uppermost surface. The method further includes forming an MRAM stack in direct contact with the uppermost surface of the first metal layer. The method further includes forming a first via layer in direct contact with the uppermost surface of the first metal layer. The method further includes forming a second metal layer in direct contact with the first via layer. The method further includes forming a second via layer in direct contact with the second metal layer. The method further includes forming a third metal layer in direct contact with the MRAM stack and in direct contact with the second via layer.

Because the first via layer, the second metal layer, and the second via layer are all arranged between the first metal layer and the third metal layer in the same manner as the MRAM cell, such embodiments of the present disclosure advantageously enable the formation of an MRAM cell in line with a via without having to increase the height of the via to accommodate the height of the MRAM cell. Accordingly, such embodiments enable in-line integration of an MRAM cell with lower level vias.

Additional embodiments of the present disclosure include a semiconductor component. The semiconductor component includes a first metal layer having an uppermost surface and a second metal layer having a lowermost surface. The semiconductor component further includes an MRAM stack in direct contact with the uppermost surface and in direct contact with the lowermost surface. The semiconductor component further includes a first via layer in direct contact with the uppermost surface. The semiconductor component further includes a second via layer in direct contact with the lowermost surface. The second via layer includes a via. A width at the top of the via is smaller than a width at the bottom of the via. The semiconductor component further includes a third metal layer in direct contact with the first via layer and the second via layer.

Because the first via layer and the second via layer are arranged in direct contact with the uppermost surface and the lowermost surface in the same manner as the MRAM cell, such embodiments of the present disclosure advantageously enable the formation of an MRAM cell in line with a combination of interconnect structures, including a via, without having to increase the height of the via to accommodate the height of the MRAM cell. Accordingly, such embodiments enable in-line integration of an MRAM cell with lower level vias.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

FIG. 1A is a schematic diagram illustrating a portion of a semiconductor element, in accordance with embodiments of the present disclosure.

FIG. 1B is a schematic diagram illustrating a portion of a semiconductor element, in accordance with embodiments of the present disclosure.

FIG. 2 illustrates a flowchart of an example method for forming a semiconductor element, in accordance with embodiments of the present disclosure.

FIG. 3A is a schematic diagram illustrating an example semiconductor element following the performance of a portion of an example method, in accordance with embodiments of the present disclosure.

FIG. 3B is a schematic diagram illustrating an example semiconductor element following the performance of a portion of an example method, in accordance with embodiments of the present disclosure.

FIG. 3C is a schematic diagram illustrating an example semiconductor element following the performance of a portion of an example method, in accordance with embodiments of the present disclosure.

FIG. 3D is a schematic diagram illustrating an example semiconductor element following the performance of a portion of an example method, in accordance with embodiments of the present disclosure.

FIG. 3E is a schematic diagram illustrating an example semiconductor element following the performance of a portion of an example method, in accordance with embodiments of the present disclosure.

FIG. 3F is a schematic diagram illustrating an example semiconductor element following the performance of a portion of an example method, in accordance with embodiments of the present disclosure.

FIG. 3G is a schematic diagram illustrating an example semiconductor element following the performance of a portion of an example method, in accordance with embodiments of the present disclosure.

FIG. 3H is a schematic diagram illustrating an example semiconductor element following the performance of a portion of an example method, in accordance with embodiments of the present disclosure.

FIG. 3I is a schematic diagram illustrating an example semiconductor element following the performance of a portion of an example method, in accordance with embodiments of the present disclosure.

FIG. 3J is a schematic diagram illustrating an example semiconductor element following the performance of a portion of an example method, in accordance with embodiments of the present disclosure.

FIG. 3K is a schematic diagram illustrating an example semiconductor element following the performance of a portion of an example method, in accordance with embodiments of the present disclosure.

FIG. 3L is a schematic diagram illustrating an example semiconductor element following the performance of a portion of an example method, in accordance with embodiments of the present disclosure.

FIG. 3M is a schematic diagram illustrating an example semiconductor element following the performance of a portion of an example method, in accordance with embodiments of the present disclosure.

FIG. 3N is a schematic diagram illustrating an example semiconductor element following the performance of a portion of an example method, in accordance with embodiments of the present disclosure.

### DETAILED DESCRIPTION

Aspects of the present disclosure relate generally to the electrical, electronic, and computer fields. In particular, the present disclosure relates to semiconductor devices including memory devices and methods of making such memory devices. While the present disclosure is not necessarily limited to such applications, various aspects of the disclosure may be appreciated through a discussion of various examples using this context.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

Turning now to an overview of technologies that are more specifically relevant to aspects of the present disclosure, random-access memory (RAM) is a form of computer memory that can be read and changed. RAM is typically used to store working data and machine code. Non-volatile random-access memory (NVRAM) is RAM that retains data without applied power. Magnetoresistive random-access memory (MRAM) is a type of NVRAM which stores data in magnetic domains.

More specifically, data in MRAM is stored by magnetic storage elements. The elements are formed from two ferromagnetic plates, each of which can hold a magnetization, separated by a thin insulating layer. One of the two plates is a permanent magnet set to a particular polarity. This plate may also be referred to as the reference layer. The other plate's magnetization can be changed to match that of an external field to store memory. This plate may also be referred to as the free layer. The thin insulating layer separating the two may also be referred to as a tunnel barrier layer, because electrons can tunnel through it from one ferromagnetic plate into the other. This configuration is known as a magnetic tunnel junction (MTJ) or an MTJ stack, and it provides the physical structure for an MRAM bit. Accordingly, this structure is also referred to herein as an MRAM stack and/or a “cell.” A memory device is built from a grid of such “cells.”

Each such cell is provided with an upper electrical contact and a lower electrical contact so that electrical current can flow through the MTJ. The upper electrical contact may also be referred to as a top electrode, and the lower electrical contact may also be referred to as a bottom electrode. The top and bottom electrodes functionally interconnect and integrate the cell into the semiconductor device by providing electrical contact with metal lines formed on different layers of the semiconductor device.

More specifically, semiconductor devices include a number of layers formed on top of one another, and electrical connection through the layers is controlled by selectively forming interconnect levels having conductive metal surrounded by insulating material. Interconnect structures include lines, which provide electrical connection within a single level, and vias, which provide electrical connection between levels in a physical electronic circuit.

In general, the various processes used to form lines and vias for a semiconductor chip or micro-chip that will be packaged into an IC fall into three general categories, namely, deposition, removal/etching, and patterning/lithography.

Deposition is any process that grows, coats, or otherwise transfers a material onto the substrate. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the substrate surface that would otherwise require higher temperatures associated with conventional CVD. Energetic ion bombardment during PECVD deposition can also improve the film's electrical and mechanical properties.

Removal/etching is any process that removes material from the substrate. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on substrates. With RIE the plasma is generated under low pressure (vacuum) by an electromagnetic field. High-energy ions from the RIE plasma attack the substrate surface and react with it to remove material.

Patterning/lithography is the formation of three-dimensional relief images or patterns on the semiconductor substrate for subsequent transfer of the pattern to a layer arranged beneath the pattern. In semiconductor lithography, the patterns are formed by a light sensitive polymer called a photoresist.

To build the complex structures that make up memory devices and other elements of an integrated circuit, lithography and etch pattern transfer steps are repeated multiple times. Each pattern being printed on the substrate is aligned to previously formed patterns, and gradually the conductive and insulative regions of multiple interconnect levels are built up to form the final device.

These processes can be used in different combinations and orders within the context of two main integration schemes for forming lines and vias. A subtractive scheme refers to processes of forming line and via structures by depositing metal, and then etching the metal to form lines and vias. Alternatively, a damascene scheme refers to the processes of forming line and via structures by depositing an oxide layer, forming a trench into the oxide layer, and then depositing metal into the trench.

In design and fabrication, layers of the device that include conductive material forming lines may also be referred to as “metal layers.” In contrast, layers of the device that include conductive material forming vias may also be referred to as “via layers,” even though the conductive material used to form the vias may be the same as that used to form the lines.

Metal layers and via layers may be formed alternatingly on top of one another in pairs. The bottommost layer is typically a via layer and may commonly be referred to as a via zero (or V0) layer. The bottommost metal layer, arranged on top of the V0 layer, may commonly be referred to as a metal one (or M1) layer, and the associated via layer, arranged on top of the M1 layer, may commonly be referred to as a via one (or V1) layer. The second to bottommost metal layer, which is built on top of the V1 layer, may commonly be referred to as a metal two (or M2) layer, and the associated via layer, arranged on top of the M2 layer, may commonly be referred to as a via two (or V2) layer. The layer numbers are incremented in this manner such that the layer number of each pair increases by one at each additional layer moving upwardly from the bottom.

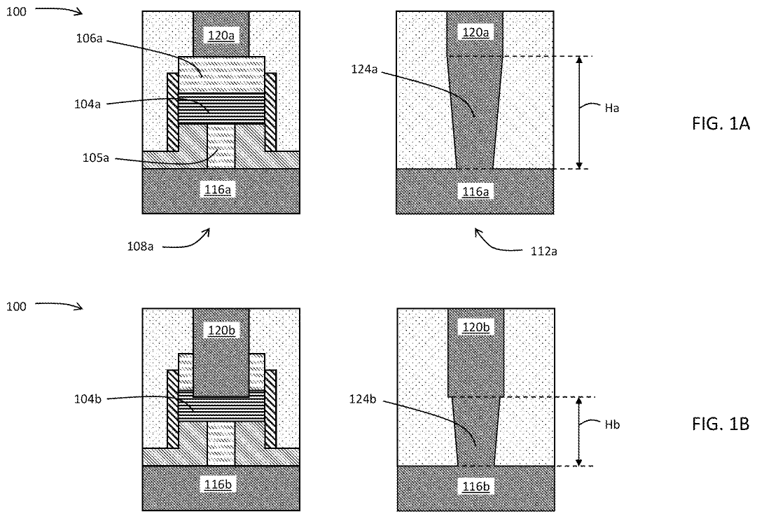

Referring now to FIG. 1A, portions of an illustrative semiconductor device 100 including an MRAM cell 104a are shown. FIG. 1A shows a memory region 108a of the device 100, which includes the MRAM cell 104a, and a logic region 112a of the device 100. As shown in FIG. 1A, it is possible to integrate an MRAM cell 104a into the memory region 108a of a semiconductor device 100 in line vertically with a via 124a correspondingly integrated into the logic region 112a of the device 100. The objective of such an arrangement is to improve the performance of the chip by reducing the vertical distance between the memory devices and the logic devices of the chip. Accordingly, the illustrative portions of the memory region 108a and logic region 112a depict the same levels of the device 100. In particular, the memory region 108a and the logic region 112a depict portions of a lower metal layer 116a and a next metal layer 120a of the device 100.

As shown, in such arrangements, the bottom electrode 105a of the MRAM cell 104a is in direct contact with the lower metal layer 116a and the top electrode 106a of the MRAM cell 104a is in direct contact with the next metal layer 120a in substantially the same manner that the via 124a is in direct contact with the lower metal layer 116a and the next metal layer 120a. In other words, in arrangements such as that shown in FIG. 1A, MRAM cells 104a in the memory region 108a are counterparts to vias 124a in the corresponding logic region 112a of a device 100, arranged in the same levels thereof. However, in order for it to be physically possible for MRAM cells 104a to be integrated into semiconductor devices 100 in this manner, the MRAM cell 104a cannot be taller than its counterpart via 124a. Otherwise, as shown in FIG. 1B, the next metal layer 120b will punch into the MRAM cell 104b.

More specifically, FIG. 1B depicts portions of the semiconductor device 100 that are substantially similar to the portions shown in FIG. 1A, except that the height Hb of the via 124b is less than a height Ha of the via 124a shown in FIG. 1A. Put another way, the height Hb of the space between the lower metal layer 116b and the next metal layer 120b is less than the height Ha of the space between the lower metal layer 116a and the next metal layer 120a. The differences in the heights Ha and Hb shown in FIGS. 1A and 1B illustrate the necessity of the height H of the via 124 being at least as large as that of the counterpart MRAM cell 104. In the illustrative semiconductor device 100 shown in FIGS. 1A and 1B, the lower metal layer 116a and the next metal layer 120a can be, for example, M5 and M6, respectively, and the lower metal layer 116b and the next metal layer 120b can be, for example, M1 and M2.

As illustrated by the contrast in the heights Ha and Hb, the height of the via level that includes the counterpart MRAM cell may be increased to accommodate the height of the MRAM cell. However, increasing the height of the via level in this manner is only possible at higher via levels (for example, V5 or V6), because increasing the via height severely degrades the performance of the logic device due to the corresponding increase in via resistance. Such a sacrifice of performance is only able to be tolerated at higher via levels (for example, V5 or V6), because increasing the height of lower via levels (for example, V1 or V2) will increase the resistance of the lower via levels outside of the target range. Therefore, from a practical functionality standpoint, MRAM cells are currently only able to be integrated into higher via levels.

Integrating MRAM cells at higher via levels, however, increases the communication delay between the MRAM cell and its associated transistor due to the discrepancy in levels. Accordingly, it is desirable to integrate MRAM cells at lower via levels to decrease the communication delay, thereby improving device performance, without having to increase the height of the via level, which introduces counterbalancing performance drawbacks.

Embodiments of the present disclosure may overcome these and other drawbacks of existing solutions by forming an MRAM cell in a memory region as a counterpart to two via levels and one intervening metal level in a logic region. As discussed in further detail below, such embodiments enable accommodation of the height of the MRAM cell in line with the counterpart via without having to increase the height of the counterpart via.

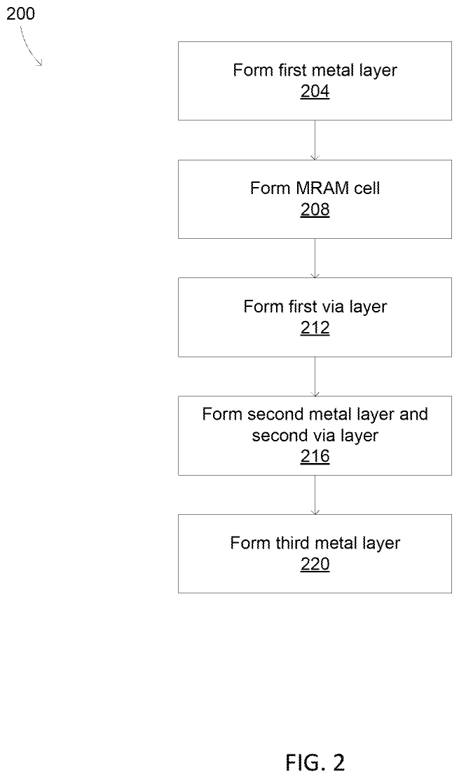

FIG. 2 depicts a flowchart of an example method 200 for forming a semiconductor device, according to embodiments of the present disclosure. The method 200 begins with operation 204, wherein a first metal layer is formed. In accordance with at least one embodiment of the present disclosure, the performance of operation 204 further includes the performance of a number of sub-operations.

More specifically, the performance of operation 204 includes forming a first layer of dielectric material on an underlying device and forming openings in the first layer of dielectric material in a memory region and in a logic region. In accordance with at least one embodiment of the present disclosure, the dielectric material can be made of, for example, a low-k dielectric material. In accordance with embodiments of the present disclosure, each opening is a line trench. In accordance with at least one embodiment of the present disclosure, the line trenches can be formed, for example, by selectively etching the first layer of dielectric material. In accordance with at least one embodiment of the present disclosure, multiple line trenches are formed in the first layer of dielectric material in each of the memory region and the logic region.

In accordance with at least one embodiment of the present disclosure, the performance of operation 204 further includes lining each of the line trenches with a liner and filling each lined line trench with a conductive material to form metal lines. This process may also be referred to as metallizing the line trenches. Typically, the conductive material is copper. Liners are typically used with copper to promote adhesion of the copper to the surrounding dielectric material and to prevent electromigration of the copper into the surrounding dielectric material. The liners are made of a material that is also conductive so that they do not prevent electrical connection therethrough, but the material is not as conductive as copper. In accordance with at least one embodiment of the present disclosure, the liners can be made of, for example, tantalum nitride or titanium nitride.

In accordance with at least one embodiment of the present disclosure, the performance of operation 204 further includes planarizing the uppermost surfaces of the first layer of dielectric material and of the conductive materials of the lines. This can be accomplished, for example, by performing chemical-mechanical planarization (CMP). Upon completion of planarization, the uppermost surfaces of the first layer of dielectric material and of the lines are substantially coplanar with one another and form an uppermost surface of the first metal layer.

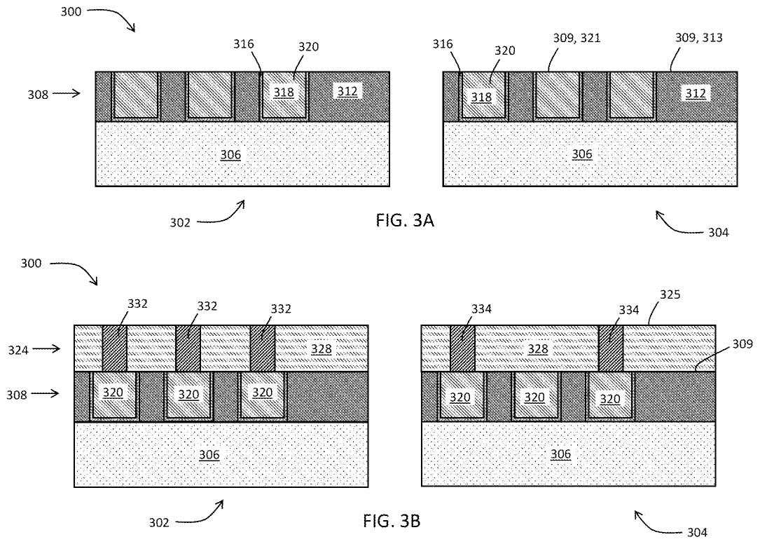

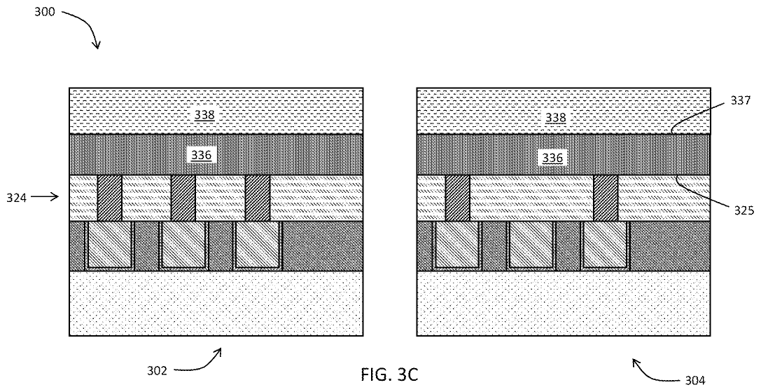

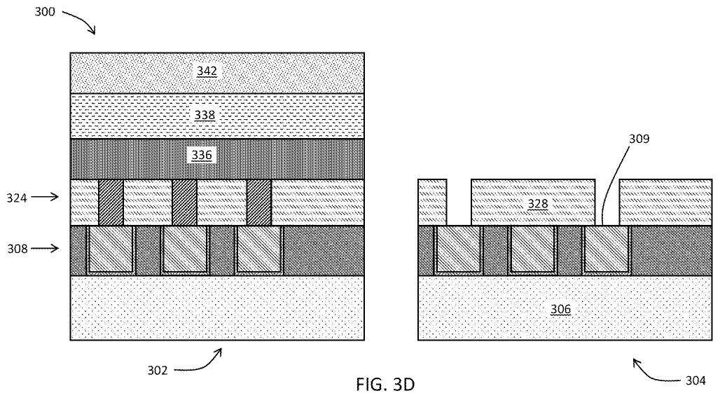

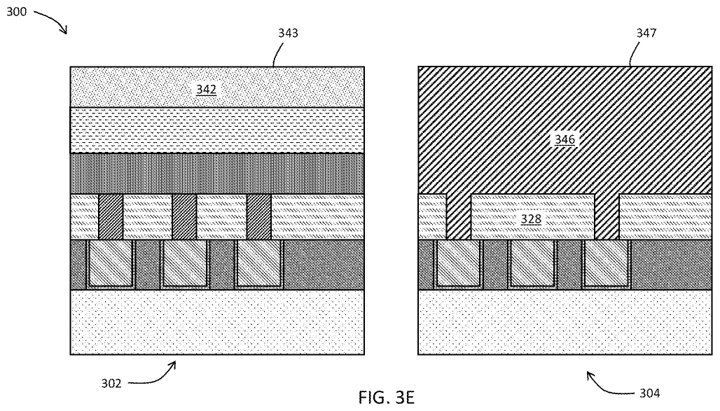

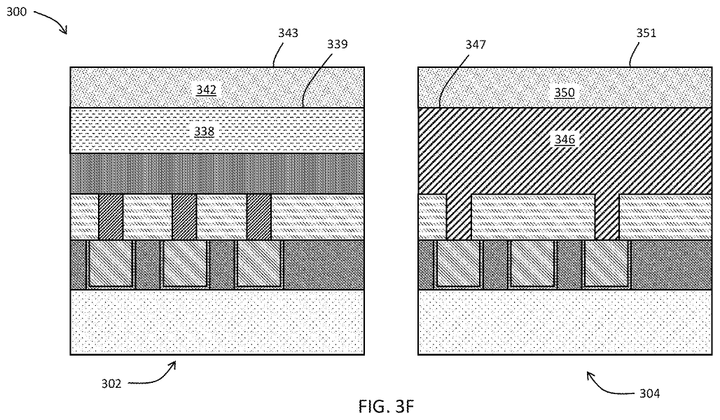

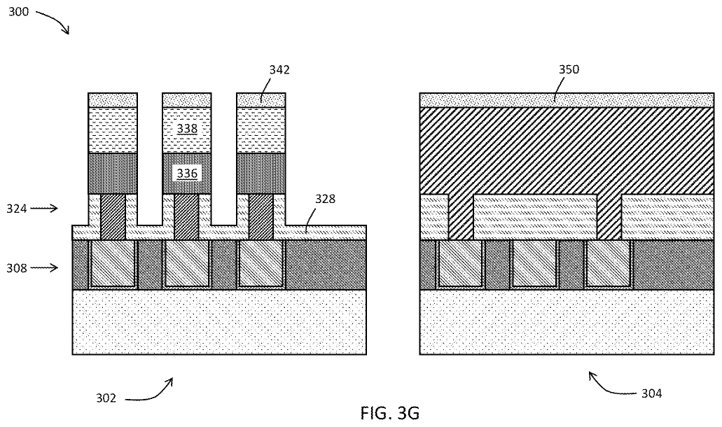

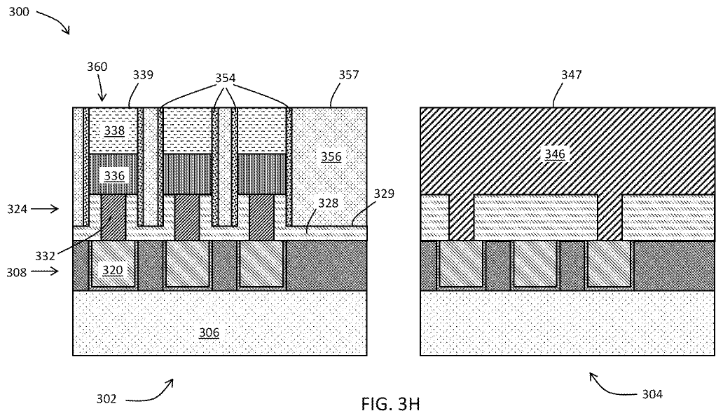

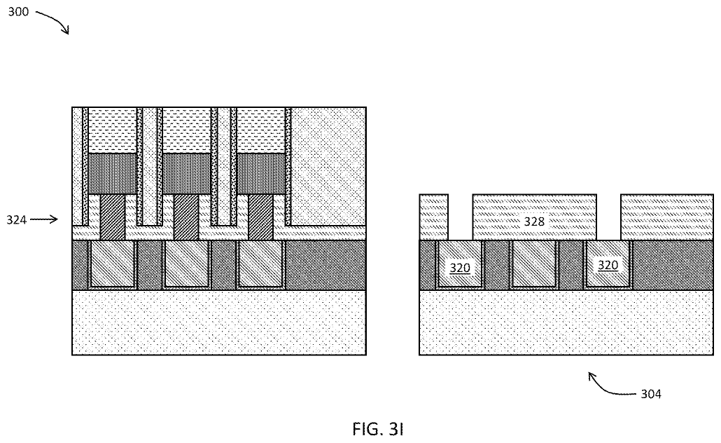

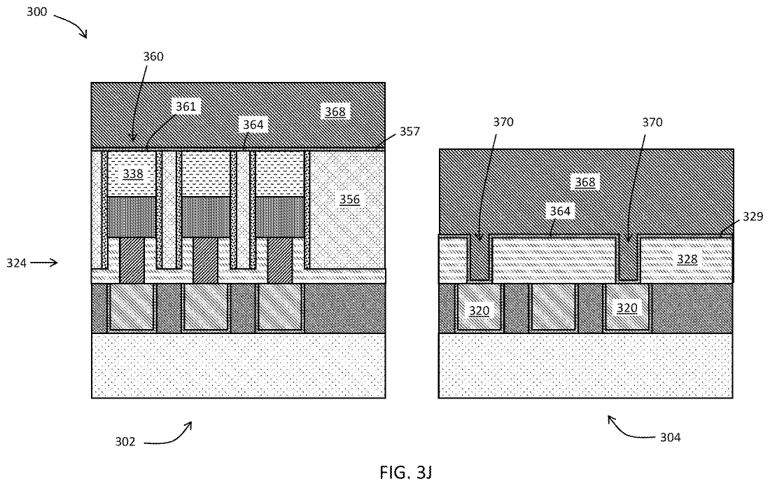

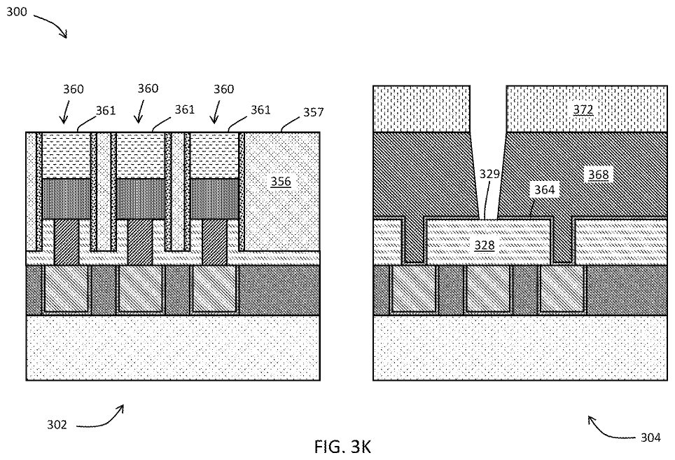

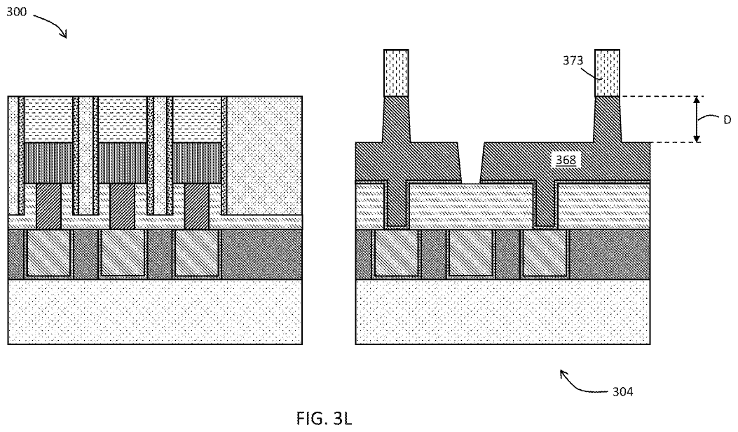

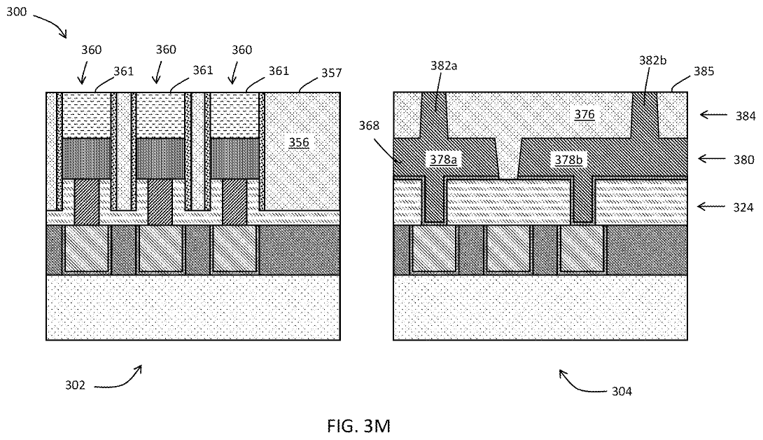

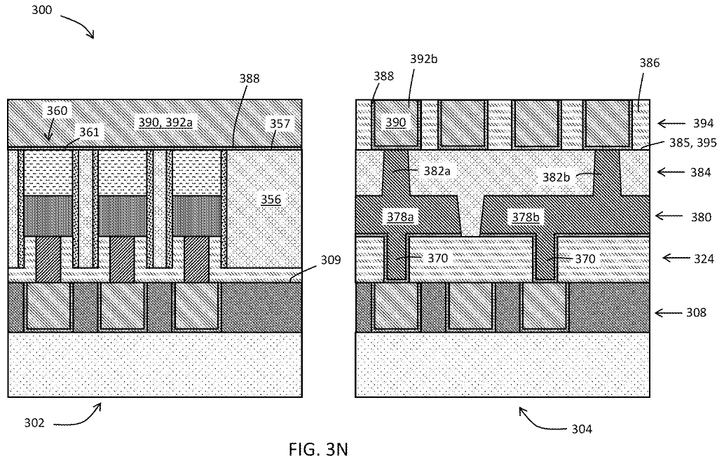

FIG. 3A depicts an example structure 300 following the performance of operation 204. In particular, FIG. 3A depicts a memory region 302 and a logic region 304 of the example structure 300. Each of the memory region 302 and the logic region 304 includes an underlying device 306 and a first metal layer 308 arranged in direct contact with the underlying device 306. The first metal layer 308 includes a first layer of dielectric material 312 formed in direct contact with the underlying device 306. The first layer of dielectric material 312 includes openings in each of the memory region 302 and the logic region 304, and each opening is lined with a liner 316, which is formed in direct contact with the first layer of dielectric material 312. Each lined opening is filled with a first conductive material 318, which is in direct contact with the liner 316, to form metal lines 320.

Each opening extends entirely through the first layer of dielectric material 312 such that the liner 316 is also in direct contact with the underlying device 306 in each of the openings. Accordingly, electrical connections with the underlying device 306 are established for each of the metal lines 320 of the first metal layer 308.

The uppermost surface 309 of the first metal layer 308 is planarized such that the uppermost surfaces 313 of the first layer of dielectric material 312 are substantially coplanar with the uppermost surfaces 321 of the metal lines 320.

Returning to FIG. 2, following the performance of operation 204, the method 200 proceeds with the performance of operation 208, wherein an MRAM cell is formed. In accordance with at least one embodiment of the present disclosure, the performance of operation 208 further includes the performance of a number of sub-operations.

More specifically, in accordance with at least one embodiment of the present disclosure, the performance of operation 208 includes forming a second layer of dielectric material on top of the first metal layer, and selectively forming openings in the second layer of dielectric material in the memory region and in the logic region. In accordance with at least one embodiment of the present disclosure, the openings can be formed, for example, by lithography followed by selectively etching the second layer of dielectric material. Each opening formed in the second layer of dielectric material in the memory region is a bottom electrode trench, and each opening formed in the second layer of dielectric material in the logic region is a via trench. In accordance with at least one embodiment of the present disclosure, multiple bottom electrode trenches and multiple via trenches are formed in the second layer of dielectric material in the memory region and the logic region, respectively.

At least one bottom electrode trench is aligned with a corresponding metal line formed in the memory region of the first metal layer, and at least one via trench is aligned with a corresponding metal line formed in the logic region. In other words, at least one bottom electrode trench exposes a portion of the uppermost surface of the corresponding metal line in the memory region and at least one via trench exposes a portion of the uppermost surface of the corresponding metal line in the logic region.

In accordance with at least one embodiment of the present disclosure, the performance of operation 208 further includes filling each of the openings with a second conductive material. The second conductive material in each of the bottom electrode trenches is in direct contact with the underlying corresponding metal line of the first metal layer and will form a bottom electrode of a corresponding MRAM cell. The second conductive material in each of the via trenches is in direct contact with the underlying corresponding metal line of the first metal layer and forms a via placeholder to retain the place for a via to be formed in a subsequent operation of the method 200.

Depending on the materials used for the second layer of dielectric material and for the conductive material, the openings may or may not be lined prior to being filled. To simplify the fabrication process, the bottom electrode trenches and the via trenches are advantageously filled in the same step with the same second conductive material. However, in the via trenches, the second conductive material acts as a sacrificial material and will be removed.

In accordance with at least one embodiment of the present disclosure, the performance of operation 208 further includes planarizing the uppermost surfaces of the second layer of dielectric material and of the second conductive material of the via placeholders and bottom electrodes. This can be accomplished, for example, by performing CMP. Upon completion of planarization, the uppermost surfaces of the second layer of dielectric material and of the conductive material forming the via placeholders and forming the bottom electrodes are substantially coplanar with one another and form an uppermost surface of the first via layer.

FIG. 3B depicts the example structure 300 following the performance of the above portions of operation 208. As shown, the example structure 300 includes a first via layer 324 formed on top of and in direct contact with the first metal layer 308 in the memory region 302 and the logic region 304. The first via layer 324 includes a second layer of dielectric material 328 formed in direct contact with the uppermost surface 309 of the first metal layer 308.

The second layer of dielectric material 328 includes openings in each of the memory region 302 and the logic region 304, and each opening is filled with a second conductive material. Each opening in the memory region 302 forms a bottom electrode trench, and the second conductive material therein forms bottom electrodes 332. Each opening in the logic region 304 forms a via trench, and the second conductive material therein forms via placeholders 334.

Each opening extends entirely through the second layer of dielectric material 328 such that the bottom electrodes 332 and the via placeholders 334 are in direct contact with the corresponding metal lines 320 on top of which they are formed, establishing electrical connections with the underlying device 306 therethrough. The uppermost surface 325 of the first via layer 324 is planarized in substantially the same manner as the uppermost surface 309 of the first metal layer 308.

In accordance with at least one embodiment of the present disclosure, the performance of operation 208 further includes forming MRAM stack and top electrode layers on top of the first via layer in the memory region of the device. In particular, MRAM stack materials are formed on top of and in direct contact with the first via layer, and a layer of a third conductive material is formed on top of and in direct contact with the MRAM stack materials. The layer of third conductive material will form the top electrode for each MRAM cell. The MRAM stack materials and the layer of third conductive material can be formed, for example, by deposition.

FIG. 3C depicts the example structure 300 following the performance of the above portions of operation 208. As shown, the example structure includes a layer of MRAM stack materials 336 and a layer of a third conductive material 338. Both layers are formed on the entire structure 300 such that they cover both the memory region 302 and the logic region 304. The MRAM stack materials 336 are therefore formed in direct contact with the entirety of the uppermost surface 325 of the first via layer 324. Similarly, the layer of the third conductive material 338 is formed in direct contact with the entirety of the uppermost surface 337 of the layer of MRAM stack materials 336.

In accordance with at least one embodiment of the present disclosure, the performance of operation 208 further includes selectively removing the MRAM stack and second and third conductive materials above the first metal layer in the logic region of the device. More specifically, a mask is applied to the memory region of the device and is not applied to the logic region of the device. The mask prevents the removal of the third conductive material forming the top electrodes, the MRAM stack materials, and the second conductive material forming the bottom electrodes from the memory region while these materials are removed from the logic region of the device.

FIG. 3D depicts the example structure 300 following the performance of the above portions of operation 208. As shown, the example structure 300 includes the layer of MRAM stack materials 336 and the layer of the third conductive material 338 in the memory region 302 covered by a memory region mask 342. In contrast, in the logic region 304 of the device 300, there is no mask, so the layer of MRAM stack materials, the layer of third conductive material forming the top electrodes, and the second conductive material that formed the via placeholders have been selectively removed. In the logic region 304, the second layer of dielectric material 328 of the first via layer 324 remains, as do the entireties of the first metal layer 308 and the underlying device 306. In other words, the second conductive material has been removed from the via trenches formed in the second layer of dielectric material 328 in the logic region 304 such that the uppermost surface 309 of the first metal layer 308 is again exposed through the openings.

In accordance with at least one embodiment of the present disclosure, the performance of operation 208 further includes forming a layer of sacrificial material to fill the via trenches formed in the second layer of dielectric material in the logic region and to cover the first via layer in the logic region. The layer of sacrificial material is formed so as to reach a height that is equal to the height of the mask in the memory region of the device. In other words, the sacrificial material is formed so that an uppermost surface of the sacrificial material in the logic region is substantially coplanar with the uppermost surface of the memory region mask in the memory region. CMP may also be used to planarize the uppermost surface of the layer of sacrificial material as well as to make the uppermost surfaces of the memory region mask and the layer of sacrificial material coplanar with one another. In accordance with at least one embodiment of the present disclosure, the sacrificial material can be, for example, a-Si. In accordance with at least one example of the present disclosure, the layer of sacrificial material can be formed by filling.

FIG. 3E depicts the example structure 300 following the performance of the above portions of operation 208. As shown, the example structure 300 includes a layer of sacrificial material 346 formed in the logic region 304 such that the sacrificial material 346 fills the via trenches formed in the second layer of dielectric material 328 and such that an uppermost surface 347 of the layer of sacrificial material 346 is substantially coplanar with an uppermost surface 343 of the memory region mask 342 in the memory region 302.

In accordance with at least one embodiment of the present disclosure, the performance of operation 208 further includes recessing the layer of sacrificial material and then applying a logic region mask over the recessed layer of sacrificial material. In accordance with at least one embodiment of the present disclosure, the layer of sacrificial material is recessed such that the uppermost surface of the layer of sacrificial material is substantially coplanar with the uppermost surface of the layer of third conductive material forming the top electrode in the memory region. The logic region mask is then applied over the recessed sacrificial layer such that the uppermost surface of the logic region mask is substantially coplanar with the uppermost surface of the mask in the memory region of the device.

FIG. 3F depicts the example structure 300 following the performance of the above portions of operation 208. As shown, the layer of sacrificial material 346 has been recessed such that the uppermost surface 347 is substantially coplanar with an uppermost surface 339 of the layer of third conductive material 338 in the memory region 302. Additionally, a logic region mask 350 has been applied on top of the uppermost surface 347 of the recessed layer of sacrificial material 346. The logic region mask 350 is applied such that an uppermost surface 351 of the logic region mask 350 is substantially coplanar with the uppermost surface 343 of the memory region mask 342. In accordance with at least one embodiment of the present disclosure, this can be achieved by applying the logic region mask 350 by depositing a hard mask material (which can be similar to that of the memory region mask 342) followed by performing CMP.

In accordance with at least one embodiment of the present disclosure, the performance of operation 208 further includes patterning the mask in the memory region and selectively removing unmasked portions of the layer of third conductive material forming the top electrodes and the layer of MRAM stack materials as well as selectively recessing unmasked portions of the second layer of dielectric material. Notably, the entireties of the unmasked portions of the second layer of dielectric material are not removed. Accordingly, the first metal layer is not exposed. In accordance with at least one embodiment, the unmasked portions of the materials may be removed, for example, by performing IBE. In addition, the thicknesses of the memory region mask and the logic region mask may be reduced.

FIG. 3G depicts the example structure 300 following the performance of the above portions of operation 208. As shown, the memory region mask 342 has been patterned in the memory region 302. In contrast, the entirety of the logic region mask 350 has been left intact. Directly beneath where the memory region mask 342 has been selectively removed in the memory region 302, the layer of third conductive material 338 and the layer of MRAM stack materials 336 have also been removed. Additionally, directly beneath where the memory region mask 342 has been selectively removed, a portion of the depth of the second layer of dielectric material 328 in the first via layer 324 has also been removed. As noted above, the first metal layer 308 has not been exposed.

In accordance with at least one embodiment of the present disclosure, the performance of operation 208 further includes forming a protective liner on the vertical lateral sides of the third layer of conductive material forming the top electrode, the layer of MRAM stack materials, and the second layer of dielectric material that were exposed by the removal illustrated in FIG. 3G. The protective liner will protect the lateral sides of these portions of the MRAM cell from being damaged during the performance of subsequent fabrication processes.

Following the formation of the protective liner, remaining space in the memory region is filled with an MRAM stack dielectric material. In at least one embodiment, the MRAM stack dielectric material can be formed by deposition. More specifically, the MRAM stack dielectric material is formed in direct contact with the protective liners and in direct contact with exposed portions of the second layer of dielectric material. The MRAM stack dielectric material is then planarized by CMP such that an uppermost surface of the MRAM stack dielectric material is substantially coplanar with the uppermost surfaces of the layer of third conductive material forming the top electrodes in the memory region and with the uppermost surface of the layer of sacrificial material in the logic region.

FIG. 3H depicts the example structure 300 following the performance of the above portions of operation 208. As shown, protective liners 354 have been formed on the laterally facing exposed sides of the layer of third conductive material 338, the layer of MRAM stack materials 336, and the second layer of dielectric material 328 in the first via layer 324. Remaining volume in the memory region 302 of the example structure 300 has been filled with MRAM stack dielectric material 356 such that the MRAM stack dielectric material 356 is in direct contact with the protective liners 354 and with exposed upwardly facing surfaces 329 of the second layer of dielectric material 328. The memory region mask 342 and the logic region mask 350 (shown in FIG. 3G) have been removed from the structure 300 during CMP processing of the MRAM stack dielectric material 356 such that an uppermost surface 357 of the MRAM stack dielectric material 356 is substantially coplanar with the uppermost surfaces 339 of the layer of third conductive material 338 in the memory region 302 and the uppermost surface 347 of the recessed layer of sacrificial material 346 in the logic region 304.

In accordance with at least some embodiments of the present disclosure, operation 208 is complete following the performance of this portion of operation 208. Accordingly, as shown in FIG. 3H, the example structure 300 includes a plurality of MRAM cells 360 in the memory region 302. Each MRAM cell 360 includes a layer of second conductive material forming the bottom electrode 332, a layer of MRAM stack materials 336, and a layer of third conductive material 338 forming the top electrode of the MRAM cell 360. Each MRAM cell 360 is electrically connected to the underlying device 306 by its direct contact with the corresponding metal line 320.

Returning to FIG. 2, following the performance of operation 208, wherein the MRAM cell is formed, the method 200 proceeds with operation 212, wherein a first via layer is formed. In accordance with at least one embodiment of the present disclosure, the performance of operation 212 further includes the performance of a number of sub-operations.

More specifically, in accordance with at least one embodiment of the present disclosure, the performance of operation 212 includes removing the layer of sacrificial material from the logic region of the device.

FIG. 3I depicts the example structure 300 following the performance of the above portions of operation 212. As shown, the layer of sacrificial material 346 (shown in FIG. 3H) has been removed from the logic region 304 of the device. Accordingly, the via trenches formed in the second layer of dielectric material 328 of the first via layer 324 are open again and the corresponding metal lines 320 are exposed therethrough.

In accordance with at least some embodiments of the present disclosure, following the removal of the layer of sacrificial material, a liner is formed in each of the via trenches and covering the uppermost surface of the second layer of dielectric material in the logic region. In accordance with at least one embodiment of the present disclosure, the liner can be made of, for example, tantalum nitride or titanium nitride. To simplify fabrication processes, when the liner is formed in the logic region, the liner is also formed in the memory region, covering the MRAM cells and the MRAM stack dielectric material.

Following the formation of the liner, a layer of fourth conductive material is formed in direct contact with the liner. The fourth conductive material can be, for example, ruthenium, copper, cobalt, or tungsten. The layer of fourth conductive material fills the lined via trenches and is also deposited on the logic region to reach a height that is substantially coplanar with the uppermost surfaces of the MRAM stacks and the uppermost surface of the MRAM stack dielectric material. To simplify fabrication processes, when the layer of fourth conductive material is formed in the logic region, the layer of fourth conductive material is also formed in the memory region, covering the liner above the MRAM cells and the MRAM stack dielectric material.

The liner and the layer of fourth conductive material form a via in each of the via trenches. Accordingly, following the performance of this portion of operation 212, the performance of operation 212 is complete.

FIG. 3J depicts the example structure 300 following the performance of the above portions of operation 212. Accordingly, as shown, a liner 364 is formed in each of the via trenches and covering the uppermost surface 329 of the second layer of dielectric material 328 in the logic region 304. Accordingly, the liner 364 is in direct contact with the corresponding metal lines 320 at the bottom of each of the via trenches. The liner 364 is also formed on uppermost surfaces 361 of the MRAM cells 360 and the uppermost surface 357 of the MRAM stack dielectric material 356 in the memory region 302.

As further shown in FIG. 3J, the structure 300 further includes a layer of fourth conductive material 368 formed in direct contact with the liner 364. The layer of fourth conductive material 368 fills each of the via trenches in the logic region 304 and covers the liner 364 in the memory region 302. The liner 364 and the layer of fourth conductive material 368 form a via 370 in each of the via trenches. Each via 370 is a first layer via in the first via layer 324.

Returning to FIG. 2, following the performance of operation 212, wherein the first via layer is formed, the method 200 proceeds with operation 216, wherein a second metal layer and a second via layer are formed. In accordance with at least one embodiment of the present disclosure, the performance of operation 216 further includes the performance of a number of sub-operations.

More specifically, in accordance with at least one embodiment of the present disclosure, the performance of operation 216 includes selectively applying a further mask to the layer of fourth conductive material in the logic region to pattern the layer of fourth conductive material in the logic region. No further mask is applied in the memory region. In particular, the further mask is applied in the logic region to form a void which will be subsequently filled with dielectric material to separate metal lines of the second metal layer from one another.

The performance of operation 216 further includes removing unmasked portions of the layer of fourth conductive material and the liner. Accordingly, the entirety of the layer of fourth conductive material and the liner are removed from the memory region. In contrast, only the unmasked portions of the layer of fourth conductive material and liner are removed from the logic region. In accordance with at least one embodiment of the present disclosure, the unmasked portions can be removed, for example, by performing an RIE procedure.

FIG. 3K depicts the example structure 300 following the performance of the above portions of operation 216. Accordingly, as shown, a further mask 372 has been applied in the logic region 304 to pattern the layer of fourth conductive material 368 in the logic region 304. Additionally, the entirety of the fourth layer of conductive material 368 and the liner 364 have been removed from the memory region 302 and have been removed from the unmasked portions of the logic region 304. Accordingly, the upwardly facing surface 329 of the second layer of dielectric material 328 is exposed where the further mask 372 was not applied in the logic region 304, and the entireties of the uppermost surfaces 357 of the MRAM stack dielectric material 356 and the uppermost surfaces 361 of the MRAM cells 360 are exposed in the memory region 302.

In accordance with at least one embodiment of the present disclosure, the performance of operation 216 further includes removing the further mask and then selectively applying a second further mask to the layer of fourth conductive material in the logic region to pattern the layer of fourth conductive material in the logic region. Alternatively, portions of the further mask can be selectively removed such that the remaining portions of the further mask form a second further mask on the layer of fourth conductive material in the logic region. None of the layer of fourth conductive material remains in the memory region, and no second further mask is applied in the memory region. The second further mask is applied in the logic region to form voids which will be subsequently filled with dielectric material to separate vias of the second via layer from one another.

The performance of operation 216 further includes removing unmasked portions of the layer of fourth conductive material down to a particular depth. As described in further detail below, the depth to which the unmasked portions of the layer of fourth conductive material are removed is the height of the vias of the second via layer. In accordance with at least one embodiment of the present disclosure, the unmasked portions can be removed, for example, by performing an RIE procedure.

FIG. 3L depicts the example structure 300 following the performance of the above portions of operation 216. Accordingly, as shown, a second further mask 373 has been applied in the logic region 304 to pattern the remaining portions of the layer of fourth conductive material 368 in the logic region 304. Additionally, unmasked portions of the layer of fourth conductive material 368 have been removed down to a depth D. In other words, the masked portions of the layer of fourth conductive material 368 extend to the depth D relative to the surrounding unmasked portions of the layer of fourth conductive material 368.

In accordance with at least one embodiment of the present disclosure, the performance of operation 216 further includes removing the second further mask from the logic region and applying a third layer of dielectric material to the logic region of the structure such that the layer of third dielectric material fills the voids formed by the selective removal of the layer of fourth conductive material. In accordance with at least one embodiment, the layer of third dielectric material can also be formed on the memory region of the structure. In either case, the performance of operation 216 further includes planarizing the uppermost surface of the layer of third dielectric material down to the uppermost surface of the vias of the second via layer formed by the layer of fourth conductive material. Accordingly, the uppermost surfaces of the second via layer and the uppermost surfaces of the MRAM cells and the MRAM stack dielectric material are substantially planar and substantially coplanar with one another.

Following the performance of this portion of operation 216, the performance of operation 216 is complete. Accordingly, following the performance of this portion of operation 216, a second metal layer and a second via layer have been formed. Notably, the metal lines of the second metal layer and the vias of the second via layer have been formed subtractively, by selectively patterning and removing portions of the layer of fourth conductive material. Additionally, the uppermost surfaces of the vias of the second via layer are substantially coplanar with the uppermost surfaces of the MRAM cells and the MRAM stack dielectric material.

FIG. 3M depicts the example structure 300 following the performance of operation 216. As shown, a layer of third dielectric material 376 has been formed in the logic region 304 such that the layer of third dielectric material 376 fills the voids formed by the selective patterning and removal of portions of the layer of fourth conductive material 368.

More specifically, the void formed using the further mask 372 (shown in FIG. 3K) has been filled with the layer of third dielectric material 376. As a result, the remaining portions of the layer of fourth conductive material 368 that are separated by this portion of the layer of third dielectric material 376 form metal lines 378a, 378b. The metal lines 378a, 378b together with the portion of the layer of third dielectric material 376 separating them from one another form a second metal layer 380.

Similarly, the voids formed using the second further mask 373 (shown in FIG. 3L) have been filled with the layer of third dielectric material 376. As a result, the remaining portions of the layer of fourth conductive material 368 that are separated by these portions of the layer of third dielectric material 376 form vias 382a, 382b. The vias 382a, 382b together with the portions of the layer of third dielectric material 376 separating them from one another form a second via layer 384.

As noted above, the metal lines 378a, 378b of the second metal layer 380 and the vias 382a, 382b of the second via layer 384 are formed subtractively. Accordingly, as an inherent structural result of being formed subtractively, the top critical dimension TCDm is smaller than the bottom critical dimension BCDm for each of the metal lines 378a, 378b. Similarly, the top critical dimension TCDv is smaller than the bottom critical dimension BCDv for each of the vias 382a, 382b.

As noted above, the uppermost surface 385 of the second via layer 384 in the logic region 304 is substantially coplanar with the uppermost surfaces 361 of the MRAM cells 360 and the uppermost surfaces 357 of the MRAM stack dielectric material 356 in the memory region 302. Additionally, the combined heights of the first via layer 324, the second metal layer 380, and the second via layer 384 are substantially equal to the height of the MRAM cells 360. In other words, the structure 300 has enabled integration of MRAM cells in line with corresponding interconnect layers without having to increase the height of a via layer.

Returning to FIG. 2, following the performance of operation 216, wherein the second metal layer and second via layer are formed, the method 200 proceeds with operation 220, wherein a third metal layer is formed. In accordance with at least one embodiment of the present disclosure, the performance of operation 220 further includes the performance of a number of sub-operations.

In accordance with at least one embodiment of the present disclosure, the performance of operation 220 includes forming a fourth layer of dielectric material on top of the second via layer in the logic region and on top of the MRAM cells and the MRAM stack dielectric material in the memory region. The performance of operation 220 further includes selectively removing portions of the fourth layer of dielectric material such that all of the fourth layer of dielectric material is removed from the memory region and such that openings are formed in the fourth layer of dielectric material in the logic region. In accordance with at least one embodiment of the present disclosure, the dielectric material can be made of, for example, a low-k dielectric material. In accordance with embodiments of the present disclosure, each opening is a line trench. In accordance with at least one embodiment of the present disclosure, the line trenches can be formed, for example, by selectively etching the fourth layer of dielectric material. In accordance with at least one embodiment of the present disclosure, multiple line trenches are formed in the fourth layer of dielectric material in the logic region.

In accordance with at least one embodiment of the present disclosure, the performance of operation 220 further includes forming a liner such that the liner covers the top of each MRAM cell and the MRAM stack dielectric material in the memory region and lines each of the line trenches in the logic region. The performance of operation 220 further includes forming a layer of fifth conductive material on top of the liner such that the fifth conductive material fills each lined line trench in the logic region, to form a metal line therein, and forms a metal line interconnecting the MRAM cells in the memory region. Typically, the conductive material is copper. Liners are typically used with copper to promote adhesion of the copper to the surrounding dielectric material and to prevent electromigration of the copper into the surrounding dielectric material. The liners are made of a material that is also conductive so that they do not prevent electrical connection therethrough, but the material is not as conductive as copper. In accordance with at least one embodiment of the present disclosure, the liners can be made of, for example, tantalum nitride or titanium nitride.

In accordance with at least one embodiment of the present disclosure, the performance of operation 220 further includes planarizing the uppermost surfaces of the fourth layer of dielectric material and of the conductive materials of the lines. This can be accomplished, for example, by performing chemical-mechanical planarization (CMP). Upon completion of planarization, the uppermost surfaces of the fourth layer of dielectric material and of the lines are substantially coplanar with one another and form an uppermost surface of the third metal layer.

FIG. 3N depicts the example structure 300 following the performance of operation 220. In particular, the structure 300 includes a fourth layer of dielectric material 386 in the logic region 304, and multiple line trenches formed therein. Each line trench extends through the entirety of the fourth layer of dielectric material 386 such that the uppermost surface 385 of the second via layer 384 is exposed therethrough. The memory region 302 does not include any of the fourth layer of dielectric material 386.

The structure 300 further includes a liner 388 and a layer of fifth conductive material 390 formed in direct contact with the liner 388. The liner 388 covers the entirety of the memory region 302, and the layer of fifth conductive material 390 covers the entirety of the liner 388. Accordingly, the liner 388 is in direct contact with the uppermost surfaces 361 of the MRAM cells 360 and with the uppermost surfaces 357 of the MRAM stack dielectric material 356, and the liner 388 and the layer of fifth conductive material 390 form a third layer metal line 392a that functionally interconnects the MRAM cells 360.

In the logic region 304, the liner 388 is in direct contact with the fourth layer of dielectric material 386 in each of the line trenches, and the layer of fifth conductive material 390 fills each lined line trench to form a third layer metal line 392b therein. The third layer metal line 392a in the memory region 302, the third layer metal lines 392b in the logic region 304, and the portions of the fourth layer of dielectric material 386 in the logic region 304 form a third metal layer 394.

Because the uppermost surface 385 of the second via layer 384, the uppermost surfaces 361 of the MRAM cells 360, and the uppermost surfaces 357 of the MRAM stack dielectric material 356 were made substantially planar and substantially coplanar with one another, a lowermost surface 395 of the third metal layer 394, formed thereon, is substantially planar.

Following the performance of operation 220, the method 200 is complete. Accordingly, the structure 300 shown in FIG. 3N is complete. As shown in FIG. 3N, each of the MRAM cells 360 spans the entirety of the distance between the uppermost surface 309 of the first metal layer 308 and the lowermost surface 395 of the third metal layer 394 in the memory region 302. Likewise, together the vias 370 of the first via layer 324, the metal lines 378a, 378b of the second metal layer 380, and the vias 382a, 382b of the second via layer 384 span the entirety of the distance between the uppermost surface 309 of the first metal layer 308 and the lowermost surface 395 of the third metal layer 394 in the logic region 304. In other words, together the first via layer 324, the second metal layer 380, and the second via layer 384 are counterparts of the MRAM cells 360. The first via layer 324, the second metal layer 380, and the second via later 384 can be considered together to form a counterpart arrangement.

Accordingly, embodiments of the present disclosure enable the integration of MRAM cells in line with corresponding interconnect layers without having to increase the height of a via layer because the subtractive patterning of the second metal layer and the second via layer after the formation of the MRAM cells allows the MRAM cell to be formed as a counterpart to two via layers and one metal layer rather than a single via layer.

The first metal layer can be represented as Mx−1, and the first via layer can be represented as Vx−1. The second metal layer, by virtue of its relative position as the next metal layer above the first metal layer, can be represented as Mx. Likewise, the second via layer, by virtue of its relative position as the next via layer above the first via layer, can be represented as Vx. Similarly, the third metal layer, by virtue of its relative position as the next metal layer above the second metal layer, can be represented as Mx+1. Notably, these relative layers can be lower level layers, such as M1, V1, M2, V2, and M3, respectively. Alternatively, these relative layers can also be higher level layers, such as M4, V4, M5, V5, and M6, respectively. Accordingly, the integration enabled by embodiments of the present disclosure is possible in lower layers of such devices as well as in higher layers.

In addition to embodiments described above, other embodiments having fewer operational steps, more operational steps, or different operational steps are contemplated. Also, some embodiments may perform some or all of the above operational steps in a different order. Furthermore, multiple operations may occur at the same time or as an internal part of a larger process.

In the foregoing, reference is made to various embodiments. It should be understood, however, that this disclosure is not limited to the specifically described embodiments. Instead, any combination of the described features and elements, whether related to different embodiments or not, is contemplated to implement and practice this disclosure. Many modifications and variations may be apparent to those of ordinary skill in the art without departing from the scope and spirit of the described embodiments. Furthermore, although embodiments of this disclosure may achieve advantages over other possible solutions or over the prior art, whether or not a particular advantage is achieved by a given embodiment is not limiting of this disclosure. Thus, the described aspects, features, embodiments, and advantages are merely illustrative and are not considered elements or limitations of the appended claims except where explicitly recited in a claim(s).

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. But, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to the skilled in the art. Therefore, it is intended that the following claims be interpreted as covering all such alterations and modifications as fall within the true spirit and scope of the invention.

What is claimed is:

1. A semiconductor component, comprising:
a first metal layer;
a second metal layer;
an MRAM cell has a height that is equal to a distance between the first metal layer and the second metal layer;
a first via layer;
a third metal layer; and
a second via layer, wherein:
the first via layer, the third metal layer, and the second via layer have a combined height that is equal to the MRAM cell height.

2. The semiconductor component of claim 1, wherein:
the MRAM cell is arranged in a memory region of the semiconductor component; and
the first via layer, the third metal layer, and the second via layer are arranged in a logic region of the semiconductor component.

3. The semiconductor component of claim 1, wherein:
the MRAM cell is arranged between the first metal layer and the second metal layer; and
the first via layer, the third metal layer, and the second via layer are arranged between the first metal layer and the second metal layer.

4. The semiconductor component of claim 1, wherein:
the MRAM cell is in direct contact with the first metal layer, and
the MRAM cell is in direct contact with the second metal layer.

5. The semiconductor component of claim 1, wherein:
the first via layer is in direct contact with the first metal layer,
the third metal layer is in direct contact with the first via layer,
the second via layer is in direct contact with the third metal layer, and
the second via layer is in direct contact with the second metal layer.

6. The semiconductor component of claim 5, wherein:
the second via layer includes a second via in direct contact with the third metal layer and in direct contact with the second metal layer,
a bottom width of the second via where the second via is in direct contact with the third metal layer is larger than a top width of the second via where the second via is in direct contact with the second metal layer.

7. A method of forming a semiconductor component, the method comprising:
forming a first metal layer;
forming an MRAM stack in direct contact with the first metal layer;
forming a layer of conductive material;
selectively removing a first portion of the layer of conductive material to form a second metal layer;
selectively removing a second portion of the layer of conductive material to form a via layer; and
forming a third metal layer in direct contact with the MRAM stack and in direct contact with the via layer.

8. The method of claim 7, further comprising:
replacing the removed first and second portions of the layer of conductive material with a first dielectric material.

9. The method of claim 7, wherein:
forming the layer of conductive material includes forming a further via in a further via layer.

10. The method of claim 9, wherein:
the further via is in direct contact with the first metal layer and is in direct contact with the second metal layer.

11. The method of claim 9, further comprising:
forming a layer of dielectric material in direct contact with the first metal layer.

12. The method of claim 11, wherein:
forming the further via includes selectively removing a portion of the layer of dielectric material to form a via trench, and
the via trench is filled with the layer of conductive material by forming the layer of conductive material.

13. A semiconductor component, comprising:
a first metal layer having a substantially planar uppermost surface;
a second metal layer spaced apart from the first metal layer, the second metal layer having a substantially planar lowermost surface;
an MRAM stack arranged in direct contact with the uppermost surface of the first metal layer and in direct contact with the lowermost surface of the second metal layer;
a counterpart arrangement arranged in direct contact with the uppermost surface of the first metal layer and in direct contact with the lowermost surface of the second metal layer, wherein:
the counterpart arrangement includes a first via layer, a third metal layer, and a second via layer.

14. The semiconductor component of claim 13, wherein:
the first via layer is in direct contact with the uppermost surface of the first metal layer, and
the second via layer is in direct contact with the lowermost surface of the second metal layer.

15. The semiconductor component of claim 13, wherein:
the second via layer includes a via in direct contact with a second metal line of the second metal layer and in direct contact with a third metal line of the third metal layer.

16. The semiconductor component of claim 15, wherein:
a top critical dimension of the via is defined by the direct contact between the via and the second metal line; and
a bottom critical dimension of the via is defined by the direct contact between the via and the third metal line.

17. The semiconductor component of claim 16, wherein:
the top critical dimension is smaller than the bottom critical dimension.

18. The semiconductor component of claim 16, wherein:
the top critical dimension is delimited by a dielectric material surrounding the via where the lowermost surface of the second metal layer is in direct contact with the dielectric material.

19. The semiconductor component of claim 16, wherein:
the bottom critical dimension is delimited by a dielectric material surrounding the via where an uppermost surface of the third metal layer is in direct contact with the dielectric material.

20. A method of forming a semiconductor component, the method comprising:
forming a first metal layer having an uppermost surface;
forming an MRAM stack in direct contact with the uppermost surface of the first metal layer;
forming a first via layer in direct contact with the uppermost surface of the first metal layer;
forming a second metal layer in direct contact with the first via layer;
forming a second via layer in direct contact with the second metal layer; and
forming a third metal layer in direct contact with the MRAM stack and in direct contact with the second via layer.

21. The method of claim 20, further comprising:
forming a first layer of dielectric material in direct contact with the uppermost surface of the first metal layer, wherein:
forming the MRAM stack in direct contact with the uppermost surface of the first metal layer includes forming a first trench in the first layer of dielectric material and forming a second trench in the first layer of dielectric material, and
forming the MRAM stack in direct contact with the uppermost surface of the first metal layer includes filling the first trench and the second trench with a first conductive material.

22. The method of claim 21, wherein:
forming the first via layer includes removing the first conductive material from the second trench and filling the second trench with a sacrificial material.

23. The method of claim 22, further comprising:
removing the sacrificial material and applying a second conductive material, wherein:
the second conductive material fills the second trench to form a first via in the first via layer, and
the second conductive material forms a metal line in the second metal layer, and a second via in the second via layer.

24. A semiconductor component, comprising:
a first metal layer having an uppermost surface;
a second metal layer having a lowermost surface;
an MRAM stack in direct contact with the uppermost surface and in direct contact with the lowermost surface;
a first via layer in direct contact with the uppermost surface;
a second via layer in direct contact with the lowermost surface, wherein the second via layer includes a via, and wherein a width at the top of the via is smaller than a width at the bottom of the via; and
a third metal layer in direct contact with the first via layer and the second via layer.

25. The semiconductor component of claim 24, wherein:
the width at the top of the via is established by direct contact between the via and the lowermost surface; and
the width at the bottom of the via is established by direct contact between the via and the third metal layer.
